(19) United States
(12) Patent Application Publication
(10) Pub. No.: US 2002/0145201 A1
(43) Pub. Date: Oct. 10, 2002

(54) Method and apparatus for making air gap insulation for semiconductor devices

(76) Inventors: Douglas Scott Armbrust, Stoneham, MA (US); Jonathan Daniel Chapple-Sokol, Essex Junction, VT (US); Anthony Kendall Stamper, Williston, VT (US)

Correspondence Address: IBM MICROELECTRONICS, INTELLECTUAL PROPERTY LAW, 1000 RIVER STREET, 972 E, ESSEX JUNCTION, VT, 05452, US

(21) Appl. No.: 09/681,437

(22) Filed: Apr. 4, 2001

(51) Int. Cl. H01L 23/48

(52) U.S. Cl. 257/776

(57) ABSTRACT

A method and apparatus for creating air gaps to act as insulators within a semiconductor die. Wires, support structures, and sacrificial structures are constructed from vias and trenches. A top layer die is subdivided so that spaces reside between each adjacent subsection. The air gaps are created by etching the sacrificial structures via allowing etchant to seep through the spaces between subsections. After the air gaps have been created, the spaces residing between the subsections are sealed.

### BACKGROUND OF THE INVENTION

1. Technical Field of the Present Invention

The present invention generally relates to semiconductor devices, and more specifically to methods and apparatuses that make air gap insulation for semiconductor devices.

2. Background of the Present Invention

A semiconductor ship consists of an array of devices whose contacts are interconnected by patterns of metal wiring. In very large scale integration (VLSI) chips, these metal patterns are multilayered and are separated by layers of insulating material, characterized by a dielectric constant. Typically, integrated circuit chip designs use one or more wiring levels having insulating or dielectric materials between the wires in each level (intralevel dielectric) and between the wiring levels (interlevel dielectric).

In VLSI chips thru the 0.18 micron generation, the insulating material is typically silicon dioxide or fluorinated silicon dioxide with a dielectric constant epsilon of about 3.5 to about 4.3. As the speed requirements and/or higher density of the chip are increased, the chip delay induced by on chip wiring Resistive and Capacitive (RC value) of the circuits must be reduced such as by lowering the circuit capacitance. One alternative for decreasing the RC value is to reduce the value of the dielectric constant materials used between the wires and wiring levels. A large number of lower dielectric constant materials are being evaluated to reduce the RC value of the circuits. These materials, which include teflon, polyarylene ethers, methyl silsesquioxane, hydrogen silsesquioxane, and SiOxCyHx, increase the difficulty of fabricating wires and vias due to their high porosity, low mechanical strength, instability at high temperature, etc. as compared to silicon dioxide. Although these low dielectric constant materials have relatitive dielectric constants under 3.5, typically in the range of 2-3, they still have a much higher relative dielectric constant than air or a vacuum.

An air gap is an ideal candidate for a dielectric constant material, since its relative dielectric constant epsilon is one (1). The use of an air gap in this fashion would require some type of air gap structure between the wires and wiring levels. Unfortunately, the use of air gap structures has been hindered with problems. Most of these problems have been associated with keeping material (e.g. packaging and passivation) from filling the air gap. Other problems have been related to maintaining the structural integrity for both long line runs and pads.

It would, therefore, be a distinct advantage to have a method and apparatus that would form air gaps between the wires and wiring levels while reducing the above noted problems. The present invention provides such a method and apparatus.

### BRIEF SUMMARY OF THE INVENTION

Summary of the Present Invention

In one aspect, the present invention is die that has been constructed to use air as an insulator where the air resides between both dummy and wire type structures that are formed with vias and trenches.

In another aspect, the present invention is a method for creating air gaps to act as insulators within a semiconductor die. The method constructs wires, support structures, and sacrificial structures out of vias and trenches. The method uses a top layer on the die that is subdivided into subsections having a space located between each adjacent subsection. The method etches the sacrificial structures by allowing etchant to seep through the spaces between the subsections. The method then seals the spaces between the subsections.

### BRIEF DESCRIPTION OF THE SEVERAL VIEWS OF THE DRAWINGS

Brief Description of the Drawings

The present invention will be better understood and its numerous advantages will become more apparent to those skilled in the art by reference to the following drawings, in conjunction with the accompanying specification, in which:

FIG. 1 is a cross-sectional view of a die having three dual damascene layers of wiring constructed in accordance with the teachings of the present invention;

FIGS. 2-6 are cross sectional views of the die of FIG. 1 as constructed in accordance with the teachings of the present invention;

FIG. 7 is an example of a die using the process described in connection with FIGS. 2-6 to construct a three dual damascene wire layers according to the teachings of the present invention;

FIG. 8 is a top view of the passivation support cap shown in FIG. 7 illustrating the arrangement of the silicon carbide blocks according to the teachings of the present invention;

FIG. 9 is a cross-sectional view of another example of a die 900 formed according to the process enumerated in FIGS. 3-8 according to the teachings of the present invention;

FIGS. 10-20 are cross-sectional views illustrating an alternative embodiment of a process for making the die of FIG. 1 according to the teachings of the present invention; and

FIG. 21 is a cross-sectional view illustrating both a wire and a support structure in detail for the first layer of air gap wiring for the die of FIG. 1 according to the teachings of the present invention.

### DETAILED DESCRIPTION OF THE INVENTION

Detailed Description of the Preferred Embodiment of the Present Invention

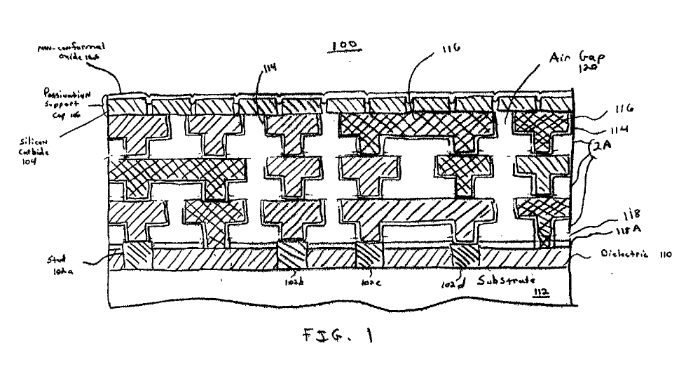

FIG. 1 is a cross-sectional view of a die 100 having three dual damascene layers of wiring constructed in accordance with the teachings of the present invention. Although three wiring levels have been illustrated in order to clearly illustrate the many advantages of the present invention, this invention is applicable to N levels of wiring, where N is greater than or equal to one. In addition, the present invention is equally applicable to both single and dual damascene methods for fabricating the wire, via, and support structures described in this disclosure.

Located on the substrate 112 is a first dielectric layer having embedded studs or interconnects 102a-d. These embedded studs or interconnects 102a-d can be, for example, standard damascene tungsten contacts going down to the devices on the silicon substrate, standard local interconnects fabricated from damascene tungsten, or any other structures. The dielectric 110 surrounding the contacts 102a-d should be a relatively hard dielectric, such as silicon dioxide, with or without boron, phosphorus, and/or flourine doping, silicon nitride, silicon carbide, or a combination of one or more layers of these types of dielectrics.

An optional Silicon Nitride (Si3N4) 118A has been placed on top of the first dielectric layer 110. The silicon Nitride layer 118A can be singular or double depending upon the amount of protection desired for the particular application. The silicon nitride layer 118A is substantially coplaner with the studs 102a-102d, and can be included to act as RIE stop for the support structures discussed below. Other dielectrics, such as silicon carbide, could be used for 118A as well.

Optional layer 118 can be used to act as an RIE stop for the subsequent damascene processing. Layer 118 can be made from materials such as silicon nitride or silicon carbide.

Layer 2A can be made from a hard dielectric, such as SiO2, or a soft dielectric, such as a Polyarylene ether (Polyarylene ethers are commercially available from companies such as Dow Chemical and Honeywell under the trademark names of SILK and FLARE, respectively.

Typical thickness' for 118 and 2A is approximately between 10-100 nm and 300-3000 nm, respectively. Intermetal dielectric 2A and optional RIE stop layer 118 are sacrificial materials that are removed later in the process to leave air gaps surrounding the damascene wiring.

Support structures 116 are made of a trough and a via which are etched into an intermetal dielectric, lined with a thin layer of silicon carbide 114, and filled with one or more conductors, such as Ta and Cu. Layer 114 insulates the support structures 116 from the damascene wires below.

The support structures 116 are distributed in a fixed density range, and provide support for wiring lines, and the passivation support dielectric cap 106. It should be noted that the spaces between the wiring are left open for occupation by air.

Located on top of the last wiring level is a passivation support cap 106 comprised of a plasma enhanced CVD (PECVD) or physical vapor deposition (PVD) silicon carbide blocks 104 with a non-conformal nitride/oxide/polymide passivation 126 formed on top thereof.

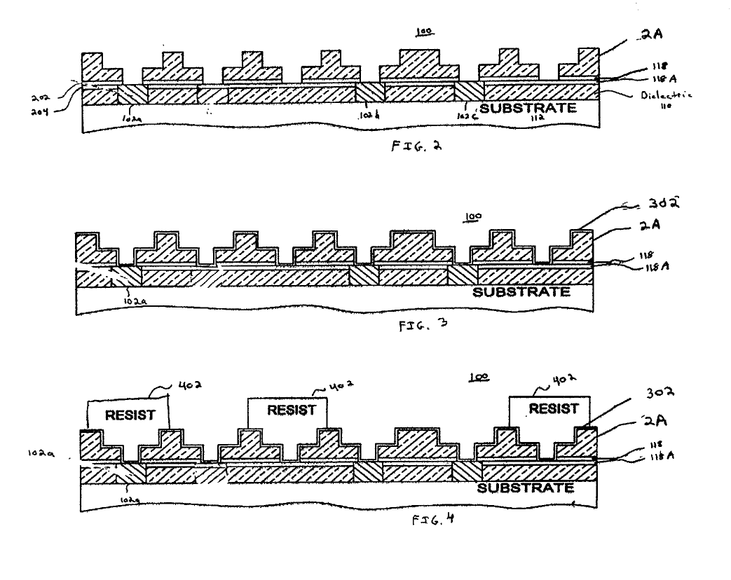

FIGS. 2 through 6 illustrate the process for constructing the die 100 of FIG. 1 according to the teachings of the present invention. The process begins (FIG. 2) by placing a first dielectric layer 110 having studs, local interconnects, wires, or vias 102a-c embedded therein on the substrate 112 using techniques that are well known and understood by those skilled in the relevant art. Studs 102a-c can be made from damascene tungsten or polysilicon contacts, local interconnects, etc.; or from any standard damascene or subtractive-etch copper or aluminum-based wiring.

Optional silicon carbide layer 118A is then placed on top of the dielectric layer 110, such that it is substantially coplanar with the tops of the studs 102a-c, using techniques that are well known and understood in the art. Optional layer 118A can be used to aid in the fabrication of the studs 102a-c, or to act as an RIE stop for the subsequent etching of the support structures 116 (FIG. 1).

A Silicon Nitride (Si3N4) layer 118 is then placed on top of the first dielectric layer 100, or optional 118a layer (as shown), using techniques that are well known (e.g. PECVD, high density plasma CVD, PVD, etc.). Although silicon nitride is preferred for layer 118, any insulative dielectric material having the appropriate etch characteristics and similar dielectric and thermal conductivity properties can be used.

Intermetal dielectric 2A is then deposited onto the Si3N4 layer 118. Layer 2A can be made from any standard dielectric appropriate for damascene processing, such as PECVD SiO2 or spin-on polyarylene ether. After the dielectric deposition, standard processing is used to fabricate dual damascene wiring trenches and vias, as known in the art. Any method, including wire trench first, via second, via first, wire trench second, or single damascene wire trench and via could be used.

The process continues (FIG. 3) by the deposition of a conformal dielectric layer 302 to a thickness ranging from 10-100 nm (preferably 50 nm) on the die 100 from FIG. 2 according to the teachings of the present invention. Layer 302 preferable can be selectively etched to the SiO2 intermetal dielectric layer 2a and is composed of silicon carbide or similar material.

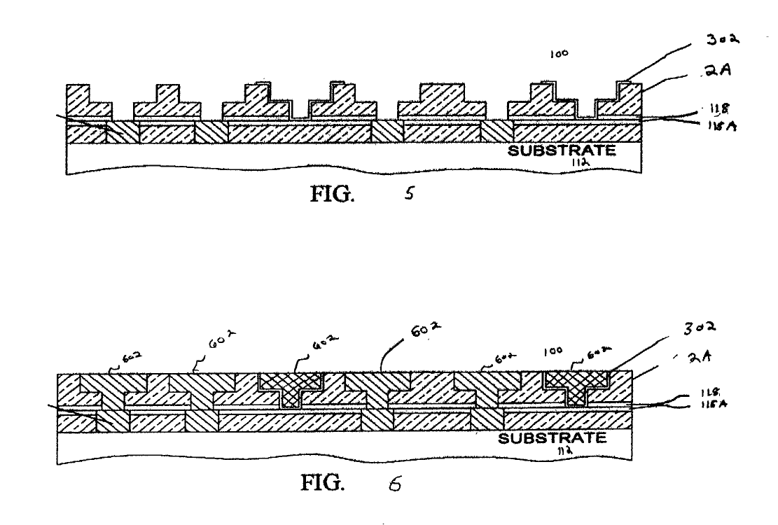

The process proceeds (FIG. 4) by applying and patterning photoresist 402 to the die of FIG. 3 to protect layer 302 in the areas where the line/via is to be turned into a support structure.

The process continues (FIG. 5) by selectively etching and removing layer 302 deposited in FIG. 3 with a wet chemical (preferred) or RIE etch to dielectric layer 2A, and stripping the photoresist using standard processes as known in the art.

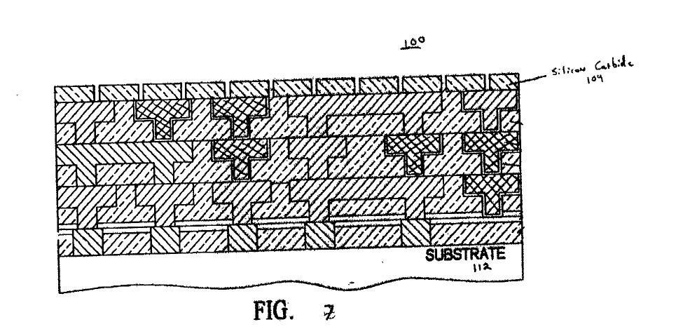

The process proceeds (FIG. 6) by depositing standard conductor materials 602, and performing CMP to damascene the conductor materials 602 into the wiring and via trenches. If the damascing wiring and support structures use copper wiring, then layer 602 be a PVD or ionized PVD deposition of TaN/Ta/Cu (˜10 nm/˜40 nm/˜100 nm) followed by a thick (˜1 micron) electroplated copper deposition. The preferred CMP process would have two steps, first a copper CMP step, followed by a TaN/Ta CMP step. Note, that although specific conductors are listed above for layer 602, any set of conductors which could be damascened into wire troughs and vias would be equally applicable to the present invention. Layer 602 could be any standard CVD or PVD or plated process.

The above noted process enumerated in FIGS. 3-6 can be repeated for the number of wiring levels desired.

FIG. 7 is an example of a die 100 using the above noted process in FIGS. 2-6 to construct a three dual damascene wire layers according to the teachings of the present invention. The construction of the die 100 continues by depositing a silicon carbide layer 104 using PECVD, PVD, etc., to a thickness of 100-3000 nm (500 nm is preferred).

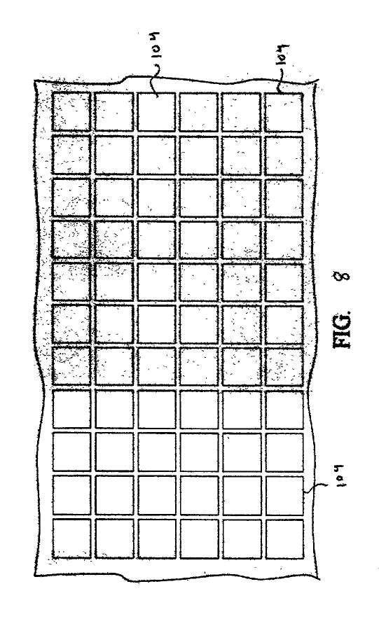

Next, photoresist is applied and patterned using a pattern shown in top view in FIG. 8, and the silicon carbide is etched down to the upper layer of damascene wiring using standard perfluorocarbon or hydrofluorocarbon RIE processes as known in the art. The spaces in layer 104 between the gaps in FIG. 8 should be large enough to provide an ingress path for the subsequent etchant but not excessively large so that the subsequent dielectric deposition cannot close the gaps. A gapsize of 10-1000 nm (100 nm is preferred) can meet both requirements. Note that layer 104 is separated into rectangular shapes which rest on the surface of the damascene wires and support structures shown in FIG. 7. This means that the wire and support structures as well as the layer 104 rectangular shape size must be coordinated such that the wires and support shapes can provide adequate support for layer 104.

FIG. 8 is a top view of the passivation support cap illustrating the arrangement of the silicon carbide blocks 104 according to a preferred embodiment of the present invention. In the preferred embodiment of the present invention, the silicon carbide layer is about 0.5-micron thick, and is divided into blocks each of which are 2.0 microns square with spaces of 0.1-microns between each block. Note, that although a regular array of square blocks are shown in FIG. 8, any pattern could be used which would allow the subsequent etchant into the damascene wire and via dielectric layers would be applicable. Additionally, if it was desired to leave some of the dielectric layers in some portions of the chip, then the mask pattern shown in FIG. 8 could be modified so as not to have opens in the desired areas. This might be desirable, for example, in regions of the chip which require the intermetal dielectric to act as a thermal conductor (e.g. in high current carrying wires or electrostatic discharge sensitive wires), or where laser-deletable fuses will be located. To prevent the intermetal dielectric in a desired region of the wafer from being etched, a vertical etch barrier, composed of wires and via bars, would be needed.

The construction of the die 100 is continued (FIG. 7) by introducing etchant through the gaps in the silicon carbide blocks 104 to etch out the dielectric mandrel located between the support structures. If a wet chemical etchant was employed, then it would need a series of two step etch processes, with intermetal dielectric 2A etched first and optional RIE stop layer 118 etched second. If layer 2A was made of silicon dioxide, then it could be etched using a dilute hydrofluoric acid. If layer 2A was made of polyarylene ether, then it could be etched in an oxygen, hydrogen, and/or nitrogen RIE chamber.

Optional RIE stop layer 2B would be preferably etched using a wet chemical etchant, such as phosphoric acid, as known in the art. If a RIE process was employed, then standard PFC- or HFC-based chemistries could be used which were isotropic and selective to the silicon carbide blocks and damascene copper wires/vias 104.

After the etching of the mandrel has been completed, a standard wafer clean, using solvents, acids, or a reactive plasma, would be used. Next, a degas step above 100C (preferably 400C) would be preferably performed for 1-60 minutes. Thereafter, a dielectric layer is placed onto the silicon carbide blocks 104 to form the passivation support cap 120 of FIG. 1. This dielectric layer 126 would preferably be deposited using a PECVD or PVD process with poor conformality so that the openings between the blocks 104 would quickly pinch off during the deposition, with minimal dielectric deposition under the blocks. Layer 126 preferably would consist of 500 nm of PECVD silicon dioxide followed by 1000 nm of PECVD silicon nitride. Finally, a thick (1-30-micron) layer of a standard wafer passivant, such as polyimide or benzocylobutane, would be used.

FIG. 9 is a cross-sectional view of another example of a die 900 formed according to the process enumerated in FIGS. 3-8. Note, a pad structure 902 has been created with a large damascene wire structure with supporting structures underneath, and it has been opened using standard resist patterning and etching processes, as known in the art.

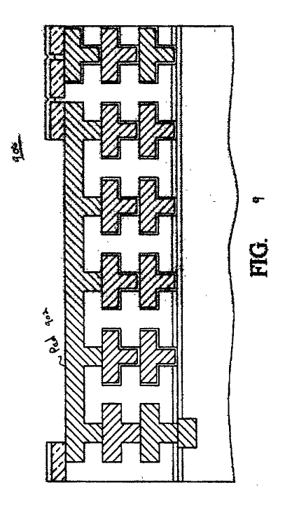

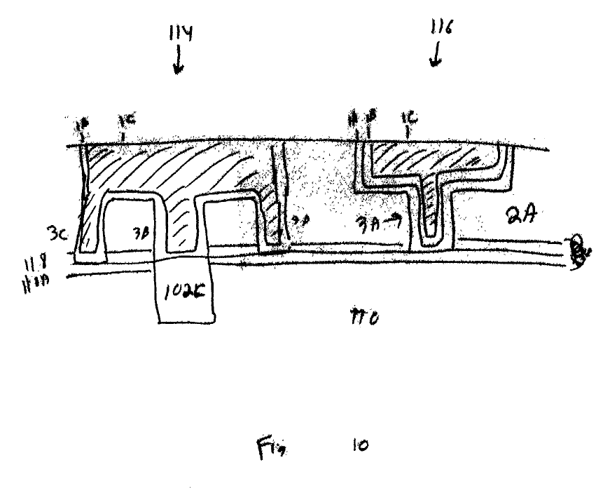

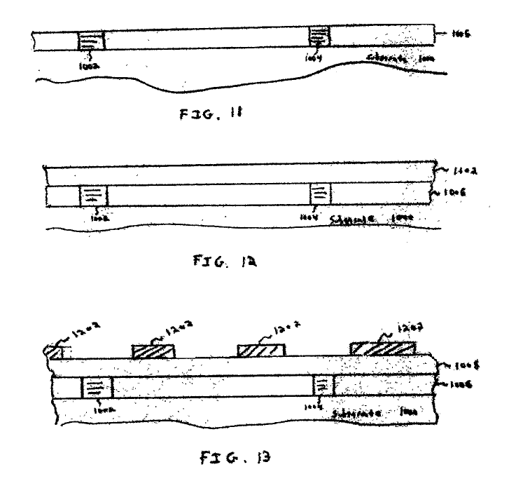

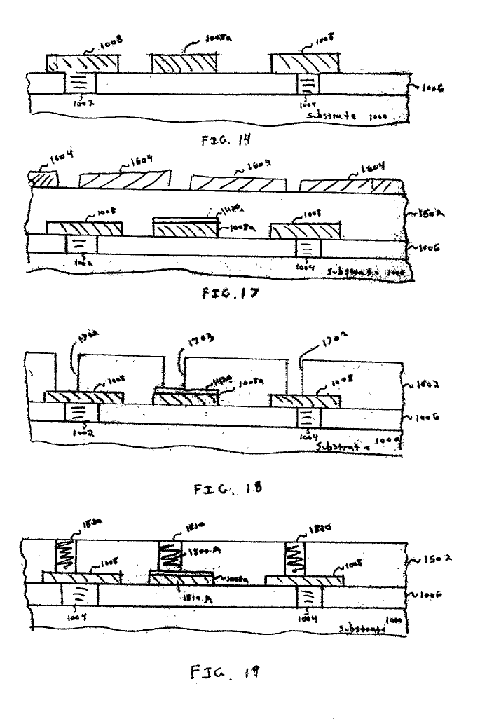

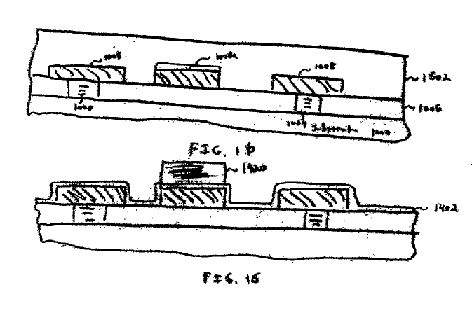

FIG. 10 shows both a wire and a support structure in detail for the first layer of airgap wiring. Wire 114 is made of conductive liner 1B and conductor 1C. Support structure 116 is made of dielectric layer 1A, conductive liner 1B, and conductor 1C. The support structure 116 would include a large number of vias 3A to provide support. Wire 114 would include as many connective vias 3B as possible as well as optional support vias 3C to provide support for the wires and support structures. Note that the circuit layout would need to be modified to accommodate the large number of support structures 116 and support vias 3C/3d which would be required for mechanical support in the air gap structure.

FIGS. 1-2 illustrate an alternative embodiment of a process for making air gap insulation in semiconductor devices.

The alternative process begins (FIG. 11) by creating a first dielectric layer 1006 having damascene studs 1002 and 1004 embedded therein and placing it on the substrate 1000 using techniques that are well known and understood by those skilled in the relevant art, as previously discussed above in reference to FIGS. 1 and 2. The dielectric 1006 surrounding the contacts 1002 and 1004 must be a relatively hard dielectric, such as silicon dioxide, with or without boron, phosphorus, and/or flourine doping, silicon nitride, silicon carbide, or a combination of one or more layers of these types of dielectrics.

The process continues (FIG. 2) by depositing a conductor layer 1102 (e.g. Ti (10 nm)/TiN (30 nm)/AlCu (500 nm)/TiN (30 nm)) on top of the dielectric 1006 using Chemical Vapor Deposition (CVD), (PVD) or the like.

The process proceeds (FIG. 3) by patterning a photoresist 1202 onto the conductor 1102 in a fashion to produce a desired support and wiring structures.

The process continues (FIG. 4) by etching the conductor 1102 according to the mask pattern 1202, resulting in support structure 1008a and wire structures 1008 being formed.

At this point (FIG. 5), a layer of approximately (˜) 10-100 nm 1420 of silicon nitride, silicon carbide, or similar material, as previously described, is deposited, and photoresist 1420 is applied and patterned such that layer 1402 is exposed and can be removed over wires 1008 where vias will subsequently need to be fabricated.

Next, layer 1402 and 1420 are etched using a PFC- or HFC-based etch process, or a wet chemical etch process, as known in the art and the photoresist is stripped (not shown).

The process proceeds (FIG. 6) to add a intermetal dielectric layer 1502 (e.g. SiO2) and perform CMP to planarize the dielectric layer 1502.

The process then continues (FIG. 7) by patterning a photoresist 1604 on top of the dielectric layer 1502 which will be used to form vias

Thereafter, the process continues (FIG. 8) by etching the dielectric layer 1502 using standard selective perflouracarbon (PFC)- or hydroflouracarbon (HFC)-based RIE chemistries as known in the art according to the mask pattern 1604 forming vias 1702 and 1703. Note, that where layer 1420 was left on the wafer, the vias are not etched down to the underlying wires and this structure 1008a and via 1703 acts as a support for the upper wiring in a similar fashion as support structures 116 (FIG. 1).

After the photoresist 1604 is stripped, the process then proceeds (FIG. 9) to fabricate damascene conductive stud vias 1830, as known in the art.

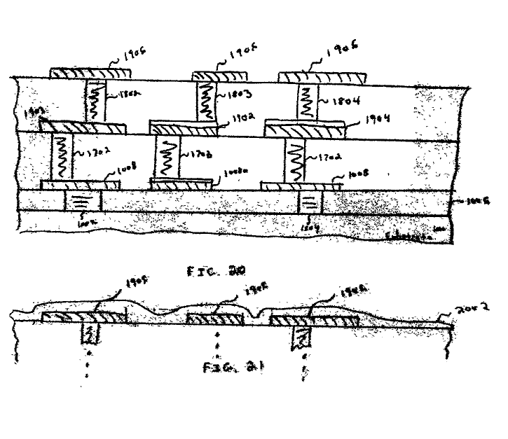

FIG. 20 shows three levels of metal wiring formed using the methods described above with dummy support structures being provided by wires 1008a, 1902, 1904 and vias 1703, 1803, and 1804. As with the damascene structures discussed previously, the dummy support structures are mixed in with the normal wires 1008, 1903, 1906, and vias fabricated 1702 and 1802 onto the wafer.

FIG. 21 shows the deposition of dielectric layer 2002 over the previously fabricated wire and supports 1906. At this point, a dielectric CMP process is performed to polish dielectric layer 2002 down to metal wiring and supports 2002 and 1906 with the CMP process stopping on the tops of 2002 and 1906. Next, a layer of silicon carbide could be deposited and patterned, similar to what was described in FIGS. 7 and 8, and the intermetal dielectric layers surrounding the wires, vias, and support structures would be etched; and the silicon carbide blocks would be passivated as previously described.

It is thus believed that the operation and construction of the present invention will be apparent from the foregoing description. While the method and system shown and described has been characterized as being preferred, it will be readily apparent that various changes and/or modifications could be made wherein without departing from the spirit and scope of the present invention as defined in the following claims.

What is claimed is:

1. A semiconductor die comprising: a top layer; a wire; and at least one dummy structure residing beneath the wire such that the combination of the dummy structure and wire provide vertical support for the top layer.

2. The semiconductor die of claim 1 wherein the dummy structure and wire are both made from a via and trench combination.

3. A method of creating air gaps as insulators within a die, the method comprising the steps of: creating a first layer on top of a substrate, the first layer having dummy structures, at least one wire, and sacrificial structures residing between the dummy structures and the at least one wire, the wire, dummy and sacrificial structures all being constructed from trenches and vias; creating a top layer residing on top of the first layer and being supported by the wire and dummy structures, the top layer having a plurality of subsections each of which have spaces residing between one another; etching the sacrificial structures by allowing etchant to seep through the spaces residing between the subsections; and sealing the top layer so that each of the spaces between the subsections are covered.

4. The method of claim 3 wherein each one of the subsections are created in a box shape.

5. The method of claim 4 wherein each one of the subsections are equal in size and shape.

6. The method of claim 4 wherein each one of the dummy structures include a via and trench combination.

7. A method of creating air gaps as insulators within a die, the method comprising the steps of: creating, on top of a substrate, a dielectric layer having studs embedded therein; placing an insulator layer on top of the dielectric layer; placing an intermetal dielectric layer on top of the insulator layer; creating a plurality of wires on top of each one of the studs; creating a plurality of dummy structures on top of the dielectric layer; creating a plurality of sacrificial structures between the dummy structures and wires; creating a top layer divided into subsections each of which are supported by either one of the wires or dummy structures, each subsection having an air gap located between adjacent subsections; etching the sacrificial structures by allowing etchant to seep through the air gaps in the subsections; and sealing the air gaps located between the subsections.

8. The method of claim 7 wherein each one of the subsections are created in a box shape.

9. The method of claim 8 wherein each one of the subsections are equal in size and shape.

10. The method of claim 7 wherein each one of the dummy structures include a via and trench combination.

11. A semiconductor die comprising: a top layer divided into a plurality of subsections, each subsection having a space between itself and an adjacent subsection; a finish layer residing on the top layer for sealing the spaces between each of the subsections.

12. The semiconductor die of claim 11 where each of the subsections has a space sufficient in size to allow enchant to seep through.

13. The semiconductor die of claim 12 wherein each one of the subsections are equal in size.
